(19) United States
(12) Patent Application Publication
(10) Pub. No.: US 2007/0217130 A1
(43) Pub. Date: Sep. 20, 2007

(54) Information processing apparatus and method of controlling the same

(75) Inventor: Michiaki Eri, Hino-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/711,038

(22) Filed: Feb. 27, 2007

(30) Foreign Application Priority Data
Feb. 28, 2006 (JP) 2006-051961

(51) Int. Cl. H05K 5/00

(52) U.S. Cl. 361/679

(57) ABSTRACT

According to one embodiment an information processing apparatus includes a display unit, a discriminator discriminating, if a window of a screen of the display unit displaying moving picture information transmitted from a terminal is overlapped by the other window, whether or not there is a viewable area in the window displaying the moving picture information, and a transmitter transmitting to the terminal an instruction signal to order transmitting moving picture information corresponding to the other area of the window displaying the moving picture information except an area where the window displaying the moving picture information and the other window overlap, if it is discriminated by the discriminator that there is a viewable area in the window displaying the moving picture information.

### CROSS-REFERENCE TO RELATED APPLICATIONS

This application is based upon and claims the benefit of priority from Japanese Patent Application No. 2006-051961, filed Feb. 28, 2006, the entire contents of which are incorporated herein by reference.

### BACKGROUND

1. Field

One embodiment of this invention relates to an information processing apparatus capable of displaying received moving pictures on a display window and a controlling method applied to the apparatus.

2. Description of the Related Art

When bi-directional communication of moving pictures is executed between personal computers, a window showing received moving pictures is often covered by the other window. Jpn. Pat. Appln. KOKAI Publication No. 10-93938 discloses a technique of, if it is discriminated that a window showing the received moving pictures is completely covered by the other window, urging a transmitter to stop transmission of the moving pictures, and, if it is discriminated that the window showing the received moving pictures is completely displayed, urging the transmitter to start the transmission of the moving pictures (Jpn. Pat. Appln. KOKAI Publication No. 10-93938).

According to the above technique, however, even if a range covered by the other window is a part of the window showing the received moving pictures, the transmission of the entire moving pictures is stopped.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary a perspective view showing an outer appearance of an information processing apparatus according to a first embodiment of the present invention;

FIG. 2 is an exemplary a block diagram showing a configuration of the information processing apparatus according to the first embodiment;

FIG. 3 is an exemplary a flowchart describing a controlling method of the information processing apparatus according to the first embodiment;

FIG. 4 is an exemplary an illustration describing the controlling method of the information processing apparatus according to the first embodiment;

FIG. 5 is an exemplary a flowchart describing a controlling method of an information processing apparatus according to a second embodiment of the present invention;

FIG. 6 is an exemplary an illustration describing the controlling method of the information processing apparatus according to the second embodiment; and

FIG. 7 is an exemplary a flowchart describing another controlling method of an information processing apparatus according to the second embodiment.

### DETAILED DESCRIPTION

Various embodiments according to the invention will be described hereinafter with reference to the accompanying drawings. In general, according to one embodiment of the invention, an information processing apparatus, comprises: a display unit; a discriminator discriminating, if a window of a screen of the display unit displaying moving picture information transmitted from a terminal is overlapped by the other window, whether or not there is a viewable area in the window displaying the moving picture information; and a transmitter transmitting to the terminal an instruction signal to order transmitting moving picture information corresponding to the other area of the window displaying the moving picture information except an area where the window displaying the moving picture information and the other window overlap, if it is discriminated by the discriminator that there is a viewable area in the window displaying the moving picture information.

### First Embodiment

A first embodiment of the present invention will be explained below with reference to the accompanying drawings.

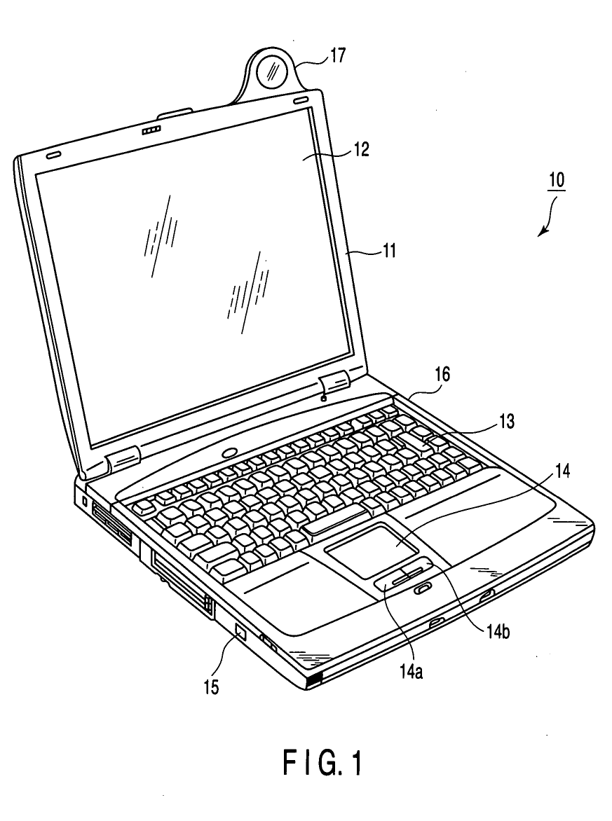

FIG. 1 is a perspective view showing an outer appearance of an information processing apparatus according to a first embodiment of the present invention. The information processing apparatus is implemented as a batter-operated notebook computer 10.

The computer 10 is composed of a main body 16 and a display unit 11 as shown in FIG. 1. A camera device 17 is arranged at an upper right side of the display unit 11. (The camera 17 may be detachable.) A display device composed of an LCD (Liquid Crystal Display) is embedded in the display unit 11. A display screen 12 of the LCD is located approximately at the center of the display unit 11.

The display unit 11 is attached to the computer 10 so as to freely pivot between an opened position and a closed position. The main body of the computer 10 has a housing shaped in a thin box, and comprises a keyboard 13 on a top face, a touch pad 14 and two buttons 14a, 14b on a palm rest. An optical drive 15 is provided on a side face of the main body 16.

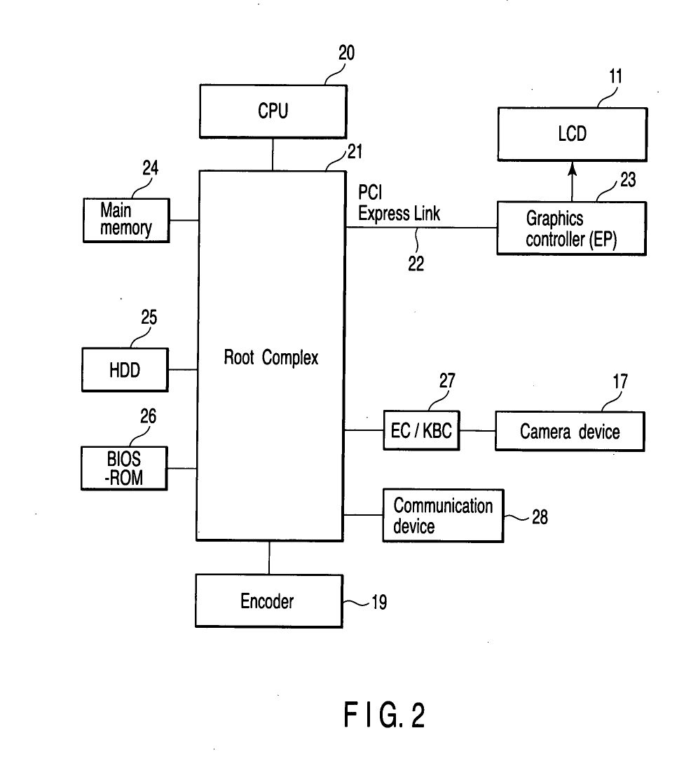

FIG. 2 is a block diagram showing the configuration of the computer.

The computer 10 comprises a CPU (Central Processing Unit) 20, a Root Complex 21, a main memory 24, a graphics controller (End Point) 23, a PCI Express Link 22 making a connection between the Root Complex 21 and the graphics controller 23, the display unit 11, an embedded controller/keyboard controller IC (EC/KBC) 27, a communication device 28 which conducts communications with the other devices via a wired or wireless network, a hard disk drive (HDD) 25, a BIOS-ROM 26, a camera device 17 serving as an input device connected to the EC/KBC 27, a moving picture encoder 19, etc.

The Root Complex 21, the graphics controller 23, etc. are devices in conformity with the PCI EXPRESS standards. The communications between the Root Complex 21 and the graphics controller 23 are executed over the PCI Express Link 22 arranged between the Root Complex 21 and the graphics controller 23.

The CPU 20 is a processor controlling the operations of the computer 10, and executes various kinds of programs (operating system and application systems) loaded on the main memory 24 by the HDD 25. The application programs include a video communication program for executing transfer of moving picture data between the computer 10 and the other computer. The video communication program has a function of urging the computer 10 to execute a processing of displaying the moving picture data transmitted from the other computer on the display screen of the display unit 11, and a processing of transmitting the moving picture data input by the camera device 17 to the other computer. Furthermore, the video communication program also has a function of, if a window displaying a received moving picture is covered even partially by the other window, not stopping the transmission of the entire moving picture, but stopping the transmission of the only moving picture corresponding to the covered area and allowing the transmission of only moving pictures corresponding to areas other than the covered area. The CPU 20 also executes the BIOS (Basic Input Output System) stored in the BIOS-ROM 26. The BIOS is a program for controlling the hardware.

The Root Complex 21 is a bridge device making a connection between a local bus of the CPU 20 and the graphics controller 23. In addition, the Root Complex 21 also has a function of executing the communications with the graphics controller 23 over the PCI Express Link 22.

The graphics controller 23 is a display controller which controls the display unit 11 employed as a display monitor of the computer.

The EC/KBC 27 is a one-chip microcomputer on which an embedded controller for power management and a keyboard controller controlling the keyboard (KB) 13 and the touch pad 14 are integrated. The EC/KBC 27 has a function of controlling power-on/power-off of the computer 10, in cooperation with a power supply controller, in response to the user's operation of the power button.

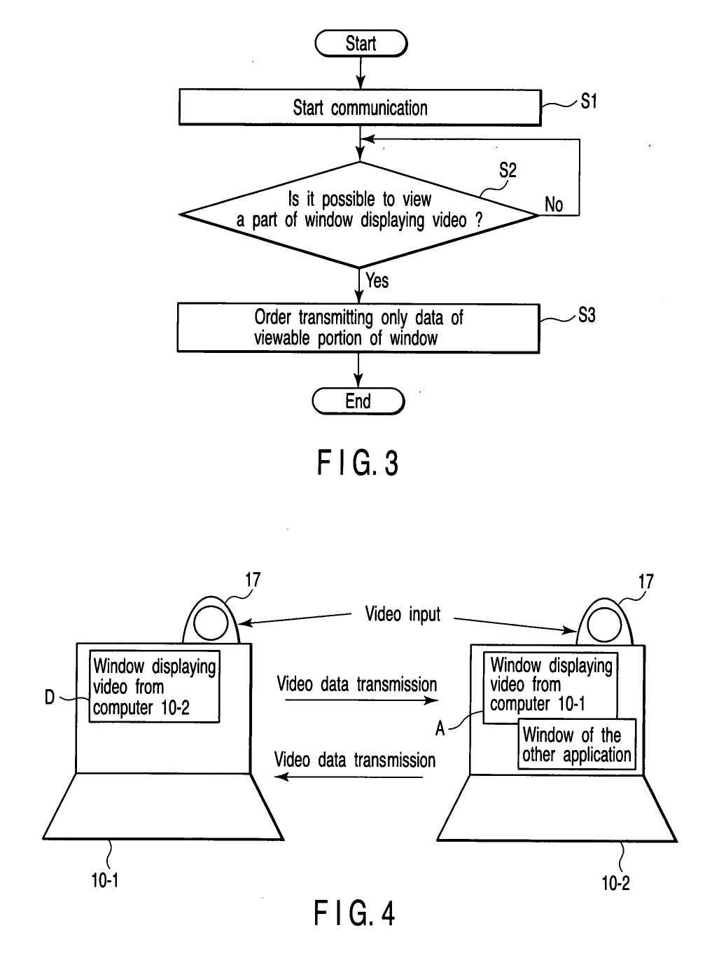

Next, a control method of the information processing apparatus according to the first embodiment of the present invention, and the video communication program in the apparatus are described with reference to a flowchart of FIG. 3 and an illustration of FIG. 4. Two computers transmitting and receiving the moving pictures are denoted as 10-1, 10-2 and the control seen from the computer 10-2 displaying two windows is described.

The CPU 20 of the computer 10-2 executes the following processing by executing the video communication program.

The CPU 20 of the computer 10-2 starts communications with the computer 10-1 with the communication device 28, receives moving picture data (hereinafter also called video data) transmitted from the computer 10-1 via the communication device 28, and displays the received video data on a window A on the display screen 12 of the display unit 11 (block S1). The video data transmitted from the computer 10-1 are, for example, moving pictures input from a camera device provided on the computer 10-1. The computer 10-2 also displays a window of the other application on the display screen 12. Similarly, the computer 10-1 receives video data transmitted from the computer 10-2 via the communication device 28 and displays the received video data on a window D. The video data transmitted from the computer 10-2 are, for example, moving pictures input from a camera device 17 provided on the computer 10-2.

If the window of the other application overlaps the window A, the CPU 20 of the computer 10-2 discriminates whether or not the window A is partially viewable, i.e. whether or not there is a viewable area in the window A (block S2). The viewable area is an area which is not covered by the window of the other application but is displayed on a front side. For example, if the window of the other application overlaps the window A and a part of the window A alone is covered by the window of the other application as shown in FIG. 4, the CPU 20 of the computer 10-2 discriminates that the widow A includes a viewable area and transmits an instruction signal to the computer 10-1 to order the computer 10-1 to transmit only video data corresponding to the viewable portion of the window A (block S3). In other words, in block S3, the CPU 20 transmits to the computer 101 serving as the terminal of the transmitter transmitting the video data, via the communication device 28, an instruction signal to order transmitting only video data corresponding to the other area (viewable portion) of the window A except an area where the window A and the window of the other application overlap.

The computer 10-1 receiving the instruction signal transmits the only video data corresponding to the viewable portion of the window A to the computer 10-2.

Thus, in the computer 10, if the window of the other application overlaps the window A displaying the received moving picture data and a part of the window A is thereby covered by the window of the other application, it is possible to prevent the video data corresponding to the covered portion of the window A from being transmitted from the transmitter terminal. Since the video data are displayed as usual on the viewable portion of the window A, unnecessary communication load caused by the transmission of the video data corresponding to the undisplayed portion can be reduced while maintaining the user convenience.

The transmission of the above instruction signal to order the transmission of the only video data corresponding to the viewable portion of the window A may be execute only in a case where the rate of the viewable area in the window A to the size of the window A (entire area of the window A) is greater than a predetermined rate.

### Second Embodiment

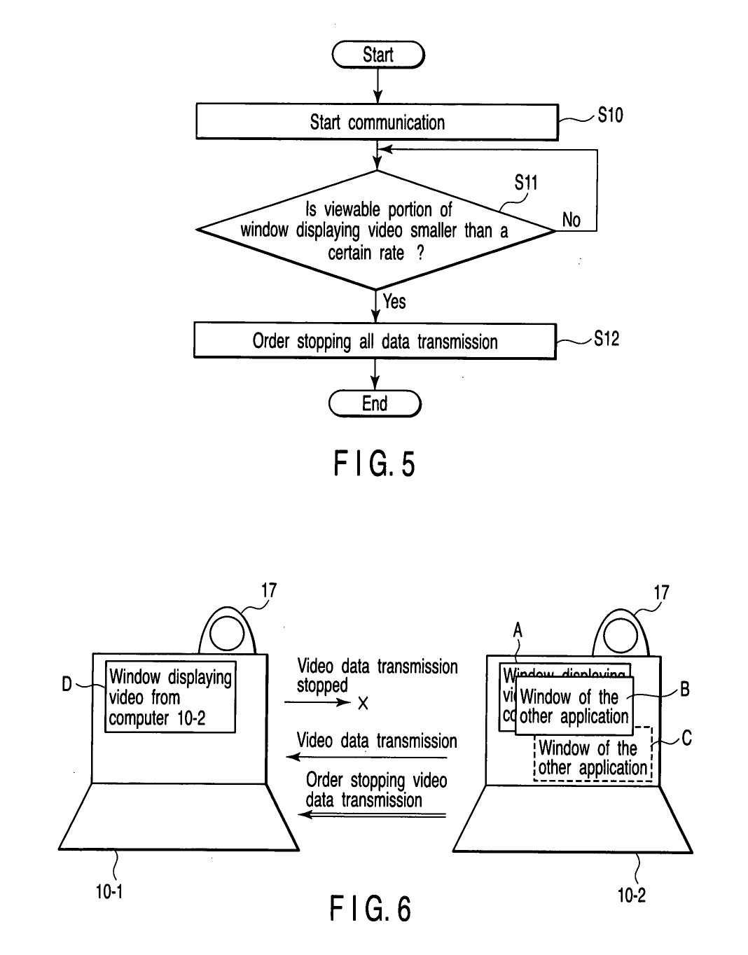

Next, a control method of the information processing apparatus according to the second embodiment of the present invention, and the video communication program in the apparatus are described with reference to a flowchart of FIG. 5 and an illustration of FIG. 6. Like elements to those of the first embodiment are denoted by the same reference numbers and their detailed descriptions are omitted.

The CPU 20 of the computer 10-2 executes the following processing by executing the video communication program.

The CPU 20 of the computer 10-2 starts communication with the computer 101 with the communication device 28, receives video data transmitted from the computer 10-1 via the communication device 28, and displays the received video data on the window A on the display screen 12 of the display unit 11 (block S10). The CPU 20 of the computer 10-2 also displays a window of the other application on the display screen 12. Similarly, the computer 10-1 receives video data transmitted from the computer 10-2 and displays the received video data on the window D.

The CPU 20 of the computer 10-2 discriminates whether or not the rate of the viewable portion in the window A to the entire area of the window A is smaller than a certain rate (for example, 20% of window A) (block S11). For example, if a window of the other application is moved from a position shown as Window C to a position shown as Window B and the window (Window B) of the other application thereby overlaps the Window A and ninety percent of the Window A is covered by the Window B as shown in FIG. 6, the CPU 20 of the computer 10-2 discriminates that the viewable portion of the Window A is smaller by twenty percent than the size of the Window A, and transmits an instruction signal to order stopping the transmission of the video data corresponding to the entire area of the Window A, i.e. stopping the transmission of the entire video data to the computer 10-1 serving as the terminal of the transmitter transmitting the video data via the communication device 28 (block S12). The computer 10-1 receiving the instruction signal stops transmitting the video data to the computer 10-2.

Thus, if the rate of the viewable portion of the Window A to the entire area of the Window A is smaller than a certain rate, the CPU 20 discriminates that the Window A is unapplicable to viewing the video data and can stop transmitting the video data corresponding to the entire area of the Window A.

The above processing of stopping transmitting the entire video data if the rate of the viewable portion of the Window A to the entire area of the Window A is smaller than a certain rate can be employed in combination of the processing of the first embodiment. In this case, the CPU 20 orders the terminal of the transmitting side to transmit the only video data corresponding to the viewable portion if the rate of the viewable portion of the Window A to the entire area of the Window A is equal to or greater than a certain rate, and the CPU 20 orders the terminal of the transmitting side to stop transmitting the entire video data if the rate of the viewable portion of the Window A to the entire area of the Window A is smaller than a certain rate.

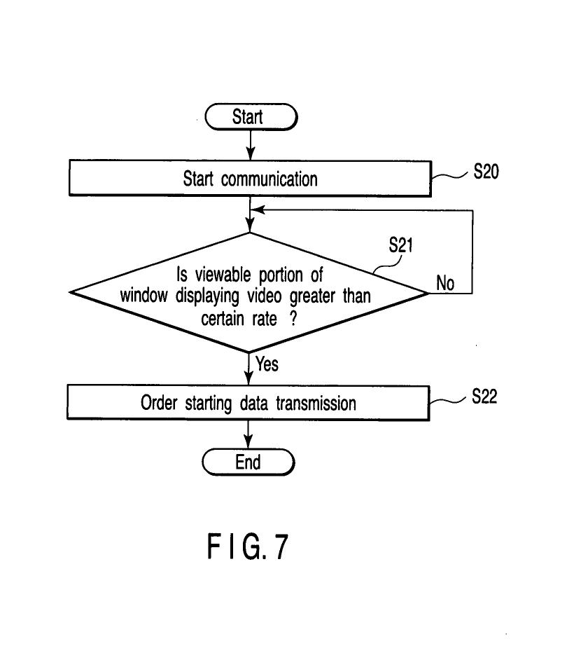

Moreover, FIG. 7 shows a case opposite to the case shown in FIG. 6. In other words, if, after the communication between the computer 10-1 and the computer 10-2 starts (block S20), a window of the other application is moved from the position shown as Window B to the position shown as Window C in FIG. 6 and the range of the Window A overlapped by the window (Window C) of the other application therefore becomes smaller and, for example, ten percent of the size of the Window A is covered by the Window B, the CPU 20 of the computer 10-2 discriminates that the rate of the viewable portion of the Window A to the entire area of the Window A is greater (for example, by twenty percent of the Window A) than a predetermined rate (block S21). The CPU 20 of the computer 10-2 transmits an instruction signal to order starting the transmission of the video data corresponding to the viewable area of the Window A, to the computer 10-1 via the communication device (block S22).

Thus, if it is discriminated that the viewable portion of the Window A is greater than a certain rate, the transmission of the video data corresponding to the viewable area of the Window A can be started.

If it is discriminated that the rate of the viewable portion of the Window A to the entire area of the Window A is greater than a specific rate (for example, eighty percent of the Window A), an instruction signal to order transmitting the video data corresponding to the entire area of the Window A, i.e. transmitting the entire video data may be transmitted to the computer 10-1. In this case, for example, the terminal of the transmitting side is ordered to transmit the video data corresponding to the only viewable portion of the Window A if the size of the viewable portion of the Window A is twenty to eighty percent of the size of the Window A, and the terminal of the transmitting side is ordered to transmit the video data corresponding to the entire area of the Window A if the viewable portion of the Window A is greater than eighty percent of the size of the Window A.

All the block S of the processing shown in each of the flowcharts of FIG. 3, FIG. 5 and FIG. 7 can be executed by the video communication program.

Therefore, the same advantage as that of each of the above embodiments can be easily achieved by installing the video communication program in a general computer having a communication function via a computer-readable storage medium.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An information processing apparatus, comprising:
a display unit;
a discriminator discriminating, if a window of a screen of the display unit displaying moving picture information transmitted from a terminal is overlapped by the other window, whether or not there is a viewable area in the window displaying the moving picture information; and
a transmitter transmitting to the terminal an instruction signal to order transmitting moving picture information corresponding to the other area of the window displaying the moving picture information except an area where the window displaying the moving picture information and the other window overlap, if it is discriminated by the discriminator that there is a viewable area in the window displaying the moving picture information.

2. The apparatus according to claim 1, wherein if it is discriminated by the discriminator that a rate of the viewable area to an entire area of the window displaying the moving picture information is greater than a predetermined rate, the transmitter transmits the instruction signal to the terminal.

3. The apparatus according to claim 1, wherein if it is discriminated by the discriminator that the rate of the viewable area to the area of the window displaying the moving picture information is smaller than a predetermined rate, the transmitter transmits an instruction signal to order stopping the transmission of the moving picture information to the terminal.

4. The apparatus according to claim 1, wherein if it is discriminated by the discriminator that a rate of the viewable area to an entire area of the window displaying the moving picture information is greater than a predetermined rate, the transmitter transmits an instruction signal to order transmission of moving picture information corresponding to the entire area of the window to the terminal.

5. A method of controlling operations of an information processing apparatus which displays moving picture information transmitted from a terminal on a window on a screen of a display device, the method comprising:
discriminating, if the window displaying the moving picture information is overlapped by the other window, whether or not there is a viewable area in the window displaying the moving picture information; and
transmitting to the terminal an instruction signal to order transmitting moving picture information corresponding to the other area of the window displaying the moving picture information except an area where the window displaying the moving picture information and the other window overlap, if it is discriminated that there is the viewable area in the window.

6. The method according to claim 5, wherein transmitting the instruction signal is executed if it is discriminated that a rate of the viewable area to an entire area of the window displaying the moving picture information is greater than a predetermined rate.

7. The method according to claim 5, further comprising transmitting an instruction signal to order stopping the transmission of the moving picture information to the terminal if it is discriminated that the rate of the viewable area to the area of the window displaying the moving picture information is smaller than a predetermined rate.

8. A program, stored in a storage medium to urge a computer to execute processing of displaying moving picture information transmitted from a terminal on a window on a screen of a display device, the program comprising:
urging the computer to execute processing of discriminating, if the window displaying the moving picture information is overlapped by the other window, whether or not there is a viewable area in the window displaying the moving picture information; and
urging the computer to execute processing of transmitting to the terminal an instruction signal to order transmitting moving picture information corresponding to the other area of the window displaying the moving picture information except an area where the window displaying the moving picture information and the other window overlap, if it is discriminated that there is the viewable area in the window.

9. The program according to claim 8, wherein transmitting the instruction signal is executed if it is discriminated that a rate of the viewable area to an entire area of the window displaying the moving picture information is greater than a predetermined rate.

10. The program according to claim 8, further comprising transmitting an instruction signal to order stopping the transmission of the moving picture information to the terminal if it is discriminated that the rate of the viewable area to the entire area of the window displaying the moving picture information is smaller than a predetermined rate.
